(19) United States
(12) Patent Application Publication
(10) Pub. No.: US 2009/0195351 A1
(43) Pub. Date: Aug. 6, 2009

(54) INFORMATION PROCESSING DEVICE AND INFORMATION PROCESSING METHOD

(75) Inventors: Naoki Takeda, Tokyo (JP); Tetsujiro Kondo, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Sony Corporation, Tokyo (JP)

(21) Appl. No.: 12/356,836

(22) Filed: Jan. 21, 2009

(30) Foreign Application Priority Data
Feb. 4, 2008 (JP) 2008-024218

(51) Int. Cl. G06F 7/04; H03G 3/00; H04N 5/445; G10L 13/00

(52) U.S. Cl. 340/5.1; 381/107; 348/564; 704/260; 348/E05.099; 704/E13.001

(57) ABSTRACT

A information processing device includes: a busy-level acquiring section for acquiring information on user's busy-level; a controller for determining a presentation form of information currently presented according to the user's busy-level acquired by the busy-level acquiring section; an information processor for performing a predetermined processing to the information under the control of the controller; and an output processor for outputting the information having been subjected to the processing by the information processor to an output section.

### CROSS REFERENCES TO RELATED APPLICATIONS

The present invention contains subject matter related to Japanese Patent Application JP 2008-024218 filed in the Japanese Patent Office on Feb. 4, 2008, the entire contents of which being incorporated herein by reference.

### BACKGROUND OF THE INVENTION

1. Field of the Invention

The present invention relates to an information processing device and an information processing method for properly changing information presentation method (i.e., information presentation form) according to user's state.

2. Description of the Related Art

When an information presentation device for presenting information of image, sound or the like is provided, a user can well understand the content of the image even using an ordinary presentation method (i.e., presentation form) if the user in a state that allows him or her to carefully view the image in no hurry. However, in some cases, the user is not in that state.

For example, the user generally can carefully view the presented image after coming back home at night, but may not carefully view the presented image before going out in the morning because he or she is in a hurry. However, in some cases, the user still wants to efficiently obtain information from the image even in the busy time in the morning. In such cases, information may not be obtained satisfactorily using an ordinary presentation method.

To solve such a problem, Japanese Unexamined Patent Application Publication No. 2007-3618, for example, descloses a technology in which biological information of the user is acquired, and the display image is controlled according to the acquired biological information.

### SUMMARY OF THE INVENTION

Although the art disclosed in Japanese Unexamined Patent Application Publication No. 2007-3618 aims to provide a user-friendly information presentation technology capable of adjusting biorhythm by acquiring biological information of the user and controlling a display image according to the acquired biological information, it is not directed to efficiently present information according to user's busy-level.

In view of the aforesaid problems, it is desirable to properly change information presentation form according to user's busy-level.

An information processing device according to an embodiment includes: a busy-level acquiring section for acquiring information on user's busy-level; a controller for determining a presentation form of information currently presented according to the user's busy-level acquired by the busy-level acquiring section; an information processor for performing a predetermined processing to the information under the control of the controller; and an output processor for outputting the information having been subjected to the processing by the information processor to an output section.

An information processing method according to another embodiment is an information processing method of an information processing device for presenting information to an output section based on information relating to a user, the method including: acquiring information on user's busy-level; determining a presentation form of information currently presented according to the acquired user's busy-level; performing a predetermined processing to the information currently presented based on the determined presentation form; and outputting the information having been subjected to the predetermined processing to the output section.

As described above, according to the aforesaid embodiments of the present invention, it is possible to properly change the information presentation form according to user's busy-level.

### BRIEF DESCRIPTION OF THE DRAWINGS

FIG. 1 is a block diagram showing an example configuration of an embodiment of a system to which an information processing device according to the present invention is applied;

FIG. 2 is a graph showing an example of measured data of acceleration of movement of a user;

FIG. 3 is a graph showing an example of measured data of heart rate of the user;

FIG. 4 is a view showing an example (in which a normal broadcast is performed) in the case where acceleration change is small;

FIG. 5 is a view showing another example (in which sound volume is increased) of the aforesaid embodiment in the case where the acceleration change is large;

FIG. 6 is a flowchart explaining a reproduction processing for implementing the information presentation form shown in FIG. 5;

FIGS. 7A and 7B are views showing further another example (in which a telop is displayed on a slave screen) of the aforesaid embodiment in the case where the acceleration change is large;

FIG. 8 is a flowchart explaining a reproduction processing for implementing the information presentation form shown in FIGS. 7A and 7B;

FIGS. 9A and 9B are views showing further another example (in which a telop is displayed on a separate screen) of the aforesaid embodiment in the case where the acceleration change is large;

FIG. 10 is a flowchart explaining a reproduction processing for implementing the information presentation form shown in FIGS. 9A and 9B;

FIG. 11 is a flowchart explaining a reproduction processing according to the aforesaid embodiment, in which presentation speed adjustment is performed;

FIG. 12 is a flowchart explaining a reproduction processing according to the aforesaid embodiment, in which digest reproduction is performed;

FIG. 13 is a view showing further another example (in which the number of programs is reduced) of the aforesaid embodiment in the case where the acceleration change is large;

FIG. 14 is a view showing further another example (in which the number of programs is increased) of the aforesaid embodiment in the case where the acceleration change is small; and

FIG. 15 is a flowchart explaining a reproduction processing for implementing the information presentation forms shown in FIGS. 13 and 14.

### DETAILED DESCRIPTION OF THE PREFERRED EMBODIMENT(S)

Examples of an embodiment of the present invention will be described below with reference to the attached drawings.

The embodiment described below is a preferred specific example of the present invention, and therefore various technically preferred limits are imposed. However, the present invention is not limited to the embodiment described below unless otherwise particularly stated. Accordingly, in the following description, for example, required material and amount thereof, processing time, processing order, value of every parameter and the like are merely preferred examples, and size, shape, arrangement and like shown in the attached drawings is merely an example roughly showing the embodiment.

In the embodiment described below, an acceleration sensor is used to explain examples of acquiring information indicating user's busy-level, but the present invention is not limited thereto.

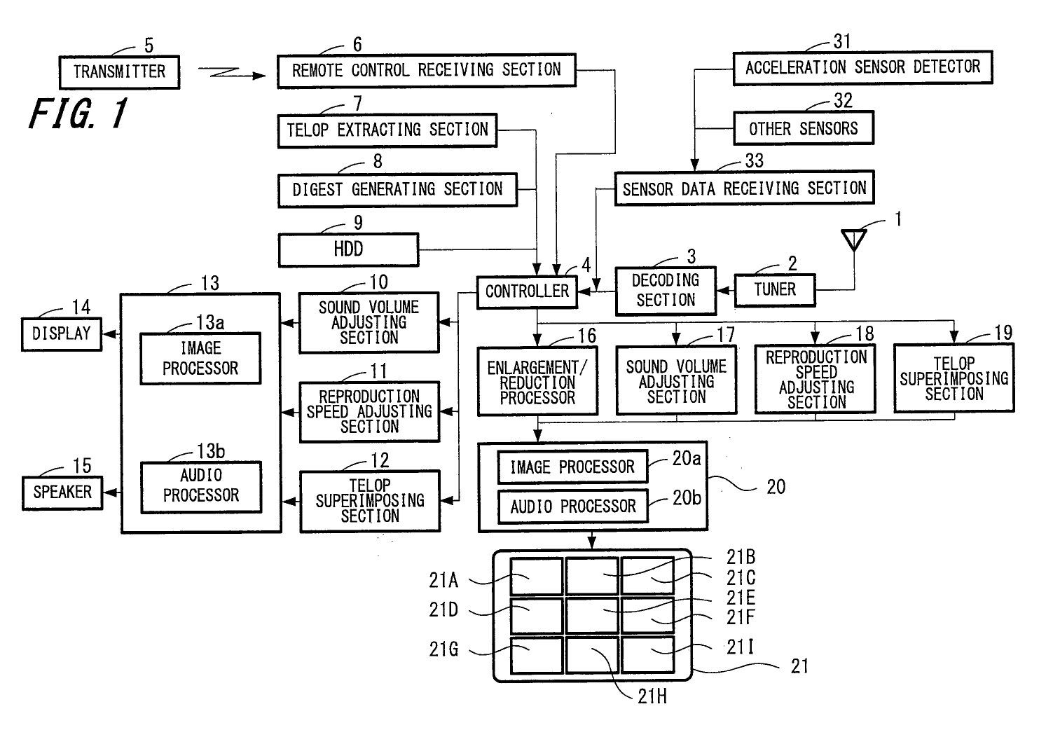

FIG. 1 is a block diagram showing an example configuration of an embodiment of a system to which an information processing device according to the present invention is applied.

The system shown in FIG. 1 includes an antenna 1, a tuner 2, a decoding section 3, a controller 4, a remote control receiving section 6, a telop extracting section 7, a digest generating section 8 and a HDD (Hard Disk Drive) 9. The system further includes a sound volume adjusting section 10, a reproduction speed adjusting section 11, a telop superimposing section 12, an output processor 13, a display 14, a speaker 15, an enlargement/reduction processor 16, a sound volume adjusting section 17, a reproduction speed adjusting section 18, a telop superimposing section 19, an output processor 20, a display device 21 and a sensor data receiving section 33.

The present embodiment is an example of applying the information processing device according to the present invention to a scalable television system (referred to as a scalable TV system hereinafter) used to display a plurality of TV programs. The scalable TV system is a system for operating a plurality of TV receivers (monitors) in concert with each other according to necessity, so that one or a plurality of images can be displayed using various methods. The technology of operating a plurality of TV receivers in concert with each other according to necessity to display the images is a well-known technology, and an example of such a technology is disclosed in Japanese Unexamined Patent Application Publication No. 2007-93702 filed by the same applicant of the present application.

The tuner 2 is installed corresponding to the TV receivers installed in the system, for example, and is adapted to extract video data and audio data of an arbitrary channel from TV signals received by the antenna 1.

The decoding section 3 is adapted to decode the coded video data and audio data included in the TV signals outputted from the tuner 2 based on a predetermined rule corresponding to the respective coding format, and to supply the decoded data to the controller 4.

The controller 4 is adapted to read out a computer program stored in a ROM (Read Only Member) of a nonvolatile memory to a PAM (Random Access Memory) of a volatile memory (not shown) to perform a predetermined control and arithmetic processing. The controller 4 can transmit control data to all blocks so as to control these blocks. For example, the controller 4 controls a predetermined block based on sensor data obtained from the sensor data receiving section 33 or other sensors 32 (which are to be described later) to make the predetermined block perform a predetermined processing.

The remote control receiving section 6 is an example of an “operation signal receiving section” (which is a more specific concept of the “busy-level acquiring section” described in Claims), and is adapted to receive an operation signal (remote control signal) such as an infrared signal or radio signal transmitted from a transmitter 5 which is an operation unit for performing remote operation, demodulate the received operation signal and supply the demodulated signal to the controller 4.

The telop extracting section 7 is adapted to extract pixel data corresponding to an artificial image such as a telop from the image signals based on the control data received from the controller 4, and an example of such a telop extracting section is disclosed in Japanese Unexamined Patent Application Publication No. 2004-318256 filed by the same applicant of the present application.

The digest generating section 8 is a block for performing a process for aggregating/editing the details of content (i.e., information) in short time under a predetermined condition based on the control data received from the controller 4 to generate a so-called digest, and supplying the generated digest to the controller 4 or HDD 9. An example of the technology for generating a digest is disclosed in Japanese Unexamined Patent Application Publication No. 2006-211311.

The HDD (hard disk drive) 9 is an example of a recording device. The HDD 9 stores and accumulates various contents such as contents of the TV programs (i.e., the video data and audio data) included in the TV signals received by the tuner 2, contents downloaded from a network and contents recorded in a recording medium such as a DVD. Further, the HDD 9 stores information such as a threshold of acceleration change, which is referred to when performing various kinds of reproduction processing (which will be described later) such as adjusting the sound volume, displaying a telop on a slave screen, displaying a telop on a separate screen, adjusting presentation speed, reproducing a digest, increasing/reducing the number of programs. Incidentally, in addition to the HDD 9, the aforesaid information may also be stored in other memories as long as these memories are nonvolatile memories, such as a semiconductor memory like a flash memory.

The sound volume adjusting section 10, the reproduction speed adjusting section 11 and the telop superimposing section 12 are each an example of the element constituting the “information processor” described in Claims.

The sound volume adjusting section 10 is adapted to adjust the sound volume of the audio data of the content presented based on the control data received from the controller 4.

The reproduction speed adjusting section 11 is adapted to adjust the reproduction speed of the content presented based on the control data received from the controller 4.

The telop superimposing section 12 is adapted to output the telop extracted by the telop extracting section 7 together with the video data of the content from which the telop is extracted.

The output processor 13 is an example of the “output processor” described in Claims. The output processor 13 includes an image processor 13a and an audio processor 13b. The output processor 13 performs a predetermined processing to the information (i.e., the video data and/or the audio data) having been subjected to a predetermined processing performed by the information processor, and supplies the result to the display 14 and/or the speaker 15.

The image processor 13a performs a predetermined image processing to the video data outputted from the information processor so that the video data can be displayed on the display 14, and supplies the result to the display 14.

The audio processor 13b performs a predetermined audio processing to the audio data outputted from the information processor, performs a processing for reproducing the audio data synchronously with the video data, and supplies the result to the speaker 15.

The display 14 is an example of the “output section” described in Claims, and is adapted to display the video data outputted from the output processor 13. Various kinds of displays such as a liquid crystal display can be used as the display 14.

The display 15 is another example of the “output section” described in Claims, and is adapted to digital/analog convert the audio data outputted from the output processor 13 and emits the sound. A flat panel speaker, a cone-shaped speaker or the like, for example, can be used as the speaker 15.

The enlargement/reduction processor 16, the sound volume adjusting section 17, the reproduction speed adjusting section 18 and the telop superimposing section 19 are each an example the element constituting the “information processor” described in Claims. Since the sound volume adjusting section 17, the reproduction speed adjusting section 18 and the telop superimposing section 19 respectively have the same functions as those of the sound volume adjusting section 10, the reproduction speed adjusting section 11 and the telop superimposing section 12, the description thereof is omitted herein.

The enlargement/reduction processor 16 is an example of the “enlargement/reduction processor” described in Claims, and is adapted to enlarge/reduce the screen size of the video data included in the contents based on the control data received from the controller 4, and change the number of contents (such as programs and the like) simultaneously displayed on a plurality of output sections, which are to be described later. The video data and audio data having been subjected to a predetermined processing performed by the enlargement/reduction processor 16, the sound volume adjusting section 17, the reproduction speed adjusting section 18 and the telop superimposing section 19 are supplied to the output processor 20.

The output processor 20 is an example of the “output processor” described in Claims. The output processor 20 includes an image processor 20a and an audio processor 20b. The output processor 20 performs a predetermined processing to the information (i.e., the video data and/or the audio data) having been subjected to the predetermined processing performed by the information processor, and supplies the result to the display device 21. Since the image processor 20a and the audio processor 20b respectively have the same functions as those of the image processor 13a and the audio processor 13b, the description thereof is omitted herein.

The display device 21 is an example of the “output section” described in Claims, and is adapted to display the video data outputted from the output processor 20. A so-called scalable TV system is used as the display device 21, which has a large screen formed by nine displays 21A to 21I, for example. Various kinds of displays such as liquid crystal displays can be used as the displays 21A to 21I, and presentation form for each of the displays (screens) is determined by the controller 4 according to the sensor data received from the sensor data receiving section 33.

In the display device 21, each of the displays is provided with a speaker (not shown) which digital/analog converts the audio data outputted from the output processor 20 and emits the sound. Similar to the speaker 15, a flat panel speaker, a cone-shaped speaker or the like can be used as the speaker of each of the displays.

Further, the system of the present embodiment is provided with the sensor data receiving section 33 as an example of the “sensor data receiving section” which is a more specific concept of the “busy-level acquiring section” described in Claims. As information indicating user's busy-level, the sensor data receiving section 33 acquires acceleration data from an acceleration sensor detector 31 attached to or held by a user. The sensor data receiving section 33 transmits the acceleration data acquired from the acceleration sensor detector 31 to the controller 4. The acceleration data is information indicating user's behavior state, and based on this information, the controller 4 estimates whether or not the user currently has much time to view the image (namely, estimates user's busy-level).

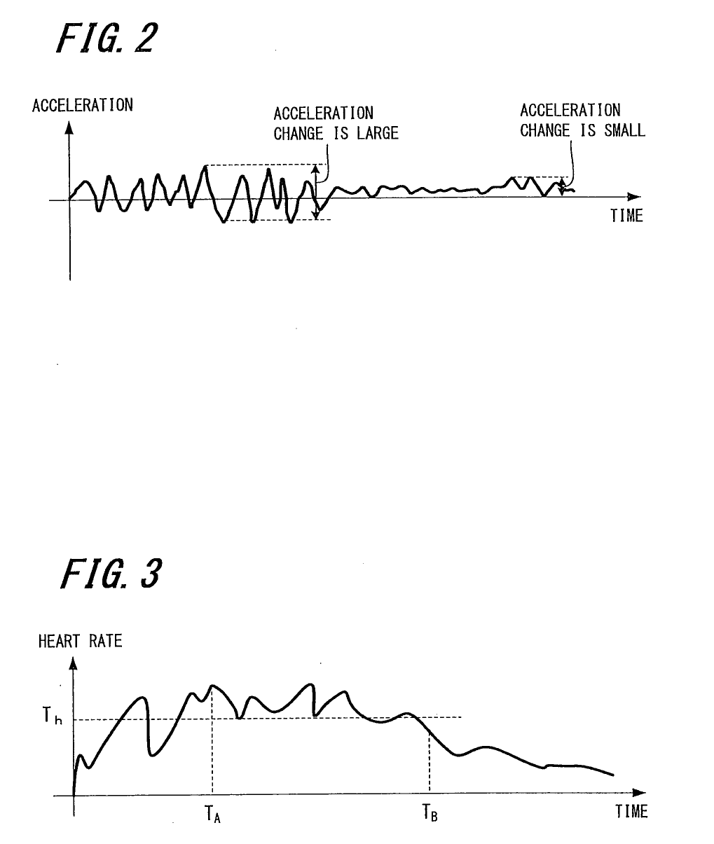

FIG. 2 is a graph showing an example of measured data of the acceleration of the movement of the user obtained by the acceleration sensor detector 31. In the graph of FIG. 2, the abscissa is time and the ordinate is the acceleration.

As can be seen from FIG. 2, in relation to the time transition, there is a portion where the acceleration change is large and a portion where the acceleration change is small. User's busy-level can be estimated by comparing the value of the detected acceleration change with a preset threshold. For example, if the acceleration change is greater than the threshold, then it can be determined that the user is moving about and therefore has no much time to view the image (namely, user's busy-level is high). While if the acceleration change is smaller than the threshold, then it can be determined that the user is not moving about and therefore has much time to view the image (namely, user's busy-level is low). In the morning, the user is usually busy and therefore has to do things in hurry, but in the night, the user relatively has time and therefore can relax himself or herself.

Further, as an example of the other sensors 32, a biological information sensor may be used for detecting biological information of the user such as heart rate, blood pressure, sweating amount and the like.

As an example, FIG. 3 shows an example of measured data of the heart rate obtained by the other sensors 32. In the graph of FIG. 3, the abscissa is time and the ordinate is the heart rate.

As can be seen from FIG. 3, in relation to the time transition, there is a portion where the heart rate is high and a portion where the heart rate is low. User's busy-level can be estimated by comparing the detected heart rate with a preset threshold. For example, if a heart rate TA is higher than a threshold Th, then it can be determined that the user is moving about and therefore has no much time to view the image (namely, user's busy-level is high). While if a heart rate TB is smaller than the threshold Th, then it can be determined that the user is not moving about and therefore has much time to view the image (namely, user's busy-level is low) Another example of the other sensors for obtaining information indicating user's busy-level is an image pickup device. For example, a video camera or the like (as the image pickup device) can be installed in a predetermined position of a room to photograph user's behavior. User's busy-level is estimated by making comparison between frames or making comparison within a frame of the photographed image to detect the moving direction and the moving distance of the user.

Under the control of the controller 4, the information processor and the information output section perform predetermined processing (which will be described later) to the contents received through the tuner 2, the contents stored in the HDD 9 and the like (i.e., the video data and audio data) based on the sensor data received by the sensor data receiving section 33. The presentation method (the presentation form) of the information presented is properly changed by outputting the video data and audio data having been subjected to the predetermined processing to the output sections.

Incidentally, although the system of the present embodiment includes the display 14 and the display device 21, the display 14 and the display device 21 may also be set outside the information processing device. Further, although the system includes both the output processor 13 and the output processor 20, the system may include either the output processor 13 or the output processor 20. For example, although the display device 21 is the scalable TV system formed by displays 21A to 21I in the present embodiment, the display 14 can be used instead of the display device 21 if the display screen of the display 14 can be divided into a plurality of display areas. Conversely, an embodiment of the present invention includes another configuration in which only the display device 21 is used, and in such a configuration the enlargement/reduction processor 16, the sound volume adjusting section 17, the reproduction speed adjusting section 18, the telop superimposing section 19 and the output processor 20 are not necessary. Further, the speaker 15 is provided to the display 14 in the present embodiment, however in the case where a plurality of displays 14 are provided, an embodiment of the present invention can be optionally designed with regard to whether or not the speaker 15 should be provided to each of the displays 14.

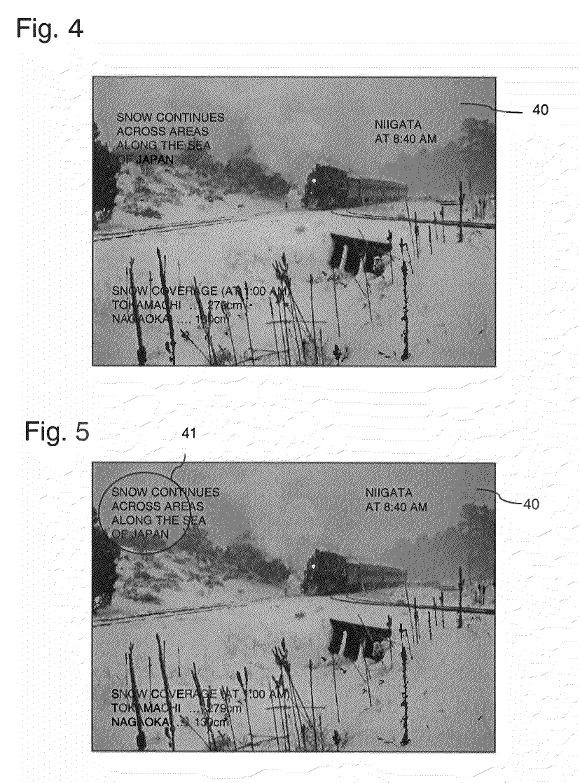

Examples of various presentation forms of the content (information) will be described below with reference to FIGS. 4 to 10.

In the following examples, although the content is subjected to a predetermined processing based on the acceleration data obtained by the acceleration sensor detector 31, the content may also be subjected to a predetermined processing based on other sensor data.

FIG. 4 is a view showing an example in the case where the acceleration change of the acceleration data detected by the acceleration sensor detector 31 is small. A news video including character information on snow coverage in every region of Japan is displayed on a screen 40 of an arbitrary display. In the present example, since the acceleration change is small, a normal broadcast is performed.

FIG. 5 is a view showing another example in which the sound volume is increased in the case where the acceleration change of the acceleration data detected by the acceleration sensor detector 31 is large. The news video including character information on snow coverage in every region of Japan is displayed on the screen 40 of an arbitrary display in the same manner as FIG. 4, but herein the sound volume is adjusted when reading aloud character information 41 of “SNOW CONTINUES ACROSS AREAS ALONG THE SEA OF JAPAN”. Incidentally, the operation of reading aloud character information can be performed using a well-known technology. For example, reading aloud character information can be achieved using a technology in which the character information is extracted from the image signals by the telop extracting section 7, the content of the extracted character information is analyzed by the controller 4, and the result is outputted as audio signals through the audio processor 20b.

With such a configuration, since the user can hear the news content about the snow coverage in voice from a remote place, the user can grasp the news content even when he or she is busy and therefore may not view the screen 40.

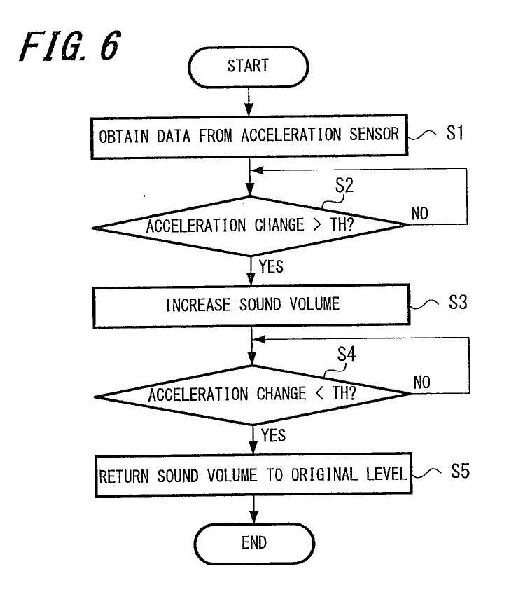

FIG. 6 is a flowchart explaining a reproduction processing as an information presentation form, in which the sound volume is adjusted.

In step S1, the sensor data receiving section 33 receives the acceleration data from the acceleration sensor detector 31, and the processing proceeds to step S2.

In step S2, the controller 4 acquires the acceleration data from the sensor data receiving section 33 and determines whether or not the acceleration change of the acceleration data is equal to or greater than a threshold TH. If it is determined that the acceleration change is smaller than the threshold TH, then the determination processing continues. In such a case, the sound volume remains at normal level.

In step S3, if it is determined in the determination processing of step S2 that the acceleration change is equal to or greater than the threshold TH, then the controller 4 determines that user's busy-level is high, and transmits control data to the sound volume adjusting section 17 to make it increase the sound volume of the audio data (the content of the character information 41, for example) Thereafter, the processing proceeds to step S4. In the case where the user can set the sound volume previously, the information can be acquired further efficiently, and operability can be further improved.

In step S4, the controller 4 determines whether or not the acceleration change is smaller than the threshold TH. If it is determined that the acceleration change is equal to or greater than the threshold TH, then the determination processing continues. In such a case, the sound volume is at high level.

In step S5, if it is determined in the determination processing of step S4 that the acceleration change is smaller than the threshold TH, then the controller 4 determines that user's busy-level is low, and transmits control data to the sound volume adjusting section 17 to make it return the sound volume of the audio data to the original level. When this process is finished, the reproduction processing accompanying sound volume adjustment is terminated.

Acquisition of the acceleration data by the acceleration sensor detector 31 is performed at a predetermined timing or periodically. Thus, when a certain time elapses after a series of the aforesaid reproduction processing is terminated, the processing shown in the flowchart of FIG. 6 will be restarted to repeat the reproduction processing accompanying sound volume adjustment.

With such a configuration, the presentation form of the information (content) presented can be properly changed according to user's busy-level (i.e., user's behavior state).

Note that, although the sound volume adjustment is described using an example in which the sound volume is increased, the sound volume adjustment may also be performed in such a manner in which the acceleration change is compared with a threshold having a smaller value, and the sound volume is reduced if the acceleration change is smaller than the threshold. Further, although the sound volume is adjusted when reading aloud the character information on the screen in the present example, the sound volume may also be adjusted when reading aloud a telop displayed on a predetermined screen (which is to be described later). Further, obviously the volume of normal sound (i.e., the sound created by program performers and/or the sound of the background displayed on the screen) may also be adjusted.

Further, although the information is displayed on the display device 21 in the present example, obviously the information may also be displayed on the display 14.

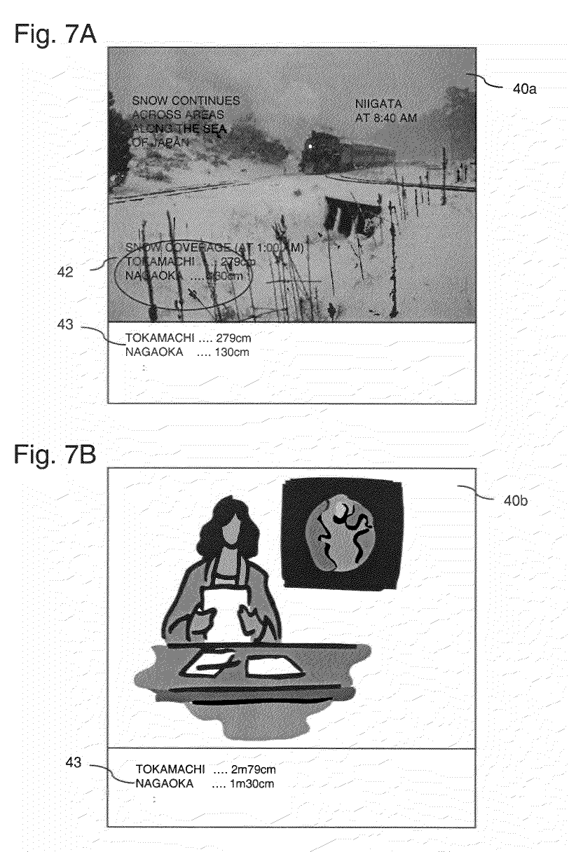

FIGS. 7A and 7B are views showing further another example in which a telop is displayed on a slave screen in the case where the acceleration change of the acceleration data detected by the acceleration sensor detector 31 is large. The news video including character information on snow coverage in every region of Japan is displayed on a screen 40a of an arbitrary display shown in FIG. 7A in the same manner as FIG. 4, but herein character information 42 of “TOKAMACHI . . . 279 cm/NAGAOKA . . . 130 cm” is displayed on a telop 43. FIG. 7B shows a circumstance in which the telop 43 is displayed on a screen 40b after the program has changed.

With such a configuration, since only a feature image is extracted to display a telop on the slave screen, the user can easily view the news content such as the snow coverage, so that the user can grasp the news content even when he or she is busy and therefore may not carefully view the screen 40a. Further, by displaying the telop 43 on the image after the image has changed from the scene of the snow coverage information report (shown in FIG. 7A) to the scene of the broadcast studio (shown in FIG. 7B), the user can know the snow coverage information later even if the he or she has missed the scene of the snow coverage information report shown in FIG. 7A.

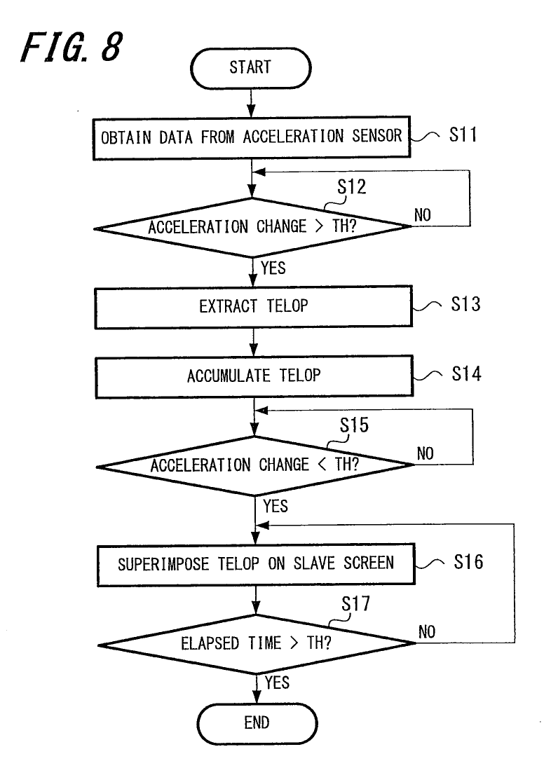

FIG. 8 is a flowchart explaining a reproduction processing as another information presentation form, in which a telop is superimposed on a slave screen.

In step S 11, the sensor data receiving section 33 receives the acceleration data from the acceleration sensor detector 31, and the processing proceeds to step S12.

In step S12, the controller 4 acquires the acceleration data from the sensor data receiving section 33 and determines whether or not the acceleration change of the acceleration data is equal to or greater than a threshold TH. If it is determined that the acceleration change is smaller than the threshold TH, then the determination processing continues.

In step S13, if it is determined in the determination processing of step S12 that the acceleration change is equal to or greater than the threshold TH, then the controller 4 determines that user's busy-level is high, and transmits control data to the telop extracting section 7 to make it extract a telop from the video data of the information (the content) to be presented. Thereafter, the processing proceeds to step S14.

In step S14, the telop extracting section 7 accumulates the extracted telop (the content of the character information 42, for example) in the HDD 9, and the processing proceeds to step S15.

In step S15, the controller 4 determines whether or not the acceleration change is smaller than the threshold TH. If it is determined that the acceleration change is equal to or higher than the threshold TH, then the processing returns to step S13 to continue extracting the telop.

In step S16, if it is determined in the determination processing of step S15 that the acceleration change is smaller than the threshold TH, then the controller 4 determines that user's busy-level is low and therefore the user is in the state that allows he or she to view the display, and transmits control data to the telop superimposing section 19 to make it superimpose a telop on a slave screen in a predetermined position. At this time, the accumulated telops are collectively displayed in a predetermined place of the slave screen. Thereafter, the processing proceeds to step S17.

In step S17, the controller 4 determines whether or not the elapsed time since the telop 43 has been superimposed on the slave screen is equal to or longer than a threshold TH. If it is determined that the elapsed time is shorter than the threshold TH, then the processing returns to step S16 to continue displaying the telop on the slave screen (see FIG. 7B, for example). In the case where the elapsed time since the telop has been displayed is taken into consideration, even if the user failed to view the telop since he or she was busy or was not in the room where the display device 21 (or display 14) is placed, the user can view the presented telop later when he or she becomes less busy. In the case where the user can set the threshold of the elapsed time previously, the information can be acquired further efficiently, and operability can be further improved.

On the other hand, if it is determined that the elapsed time is equal to or longer than the threshold TH, then the reproduction processing accompanying processing of superimposing the telop on the slave screen is terminated.

Acquisition of the acceleration data by the acceleration sensor detector 31 is performed at a predetermined timing or periodically. Thus, when a certain time elapses after a series of the aforesaid reproduction processing is terminated, the processing shown in the flowchart of FIG. 8 will be restarted to repeat the reproduction processing accompanying processing of superimposing the telop on the slave screen.

With such a configuration, the presentation form of the information (content) presented can be properly changed according to user's busy-level (i.e., user's behavior state).

Incidentally, although the information is displayed on the display device 21 in the present example, obviously the information may also be displayed on the display 14.

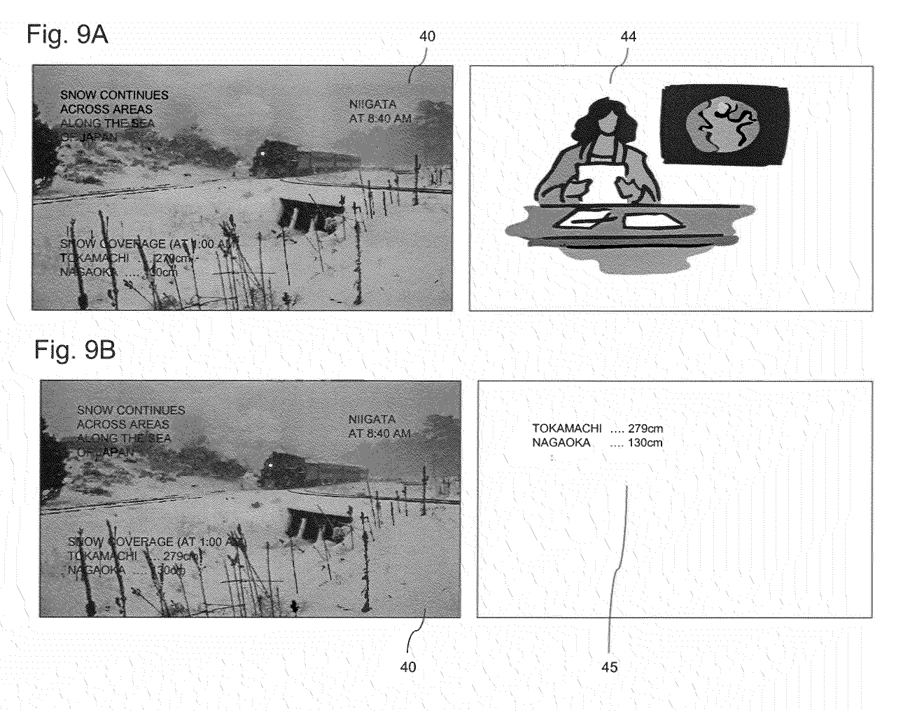

FIGS. 9A and 9B are views showing further another example in which a telop is displayed on a separate screen in the case where the acceleration change of the acceleration data detected by the acceleration sensor detector 31 is large. The news video including character information on snow coverage in every region of Japan is displayed on the screen 40 of an arbitrary display of the display device 21 shown in FIG. 9A in the same manner as FIG. 4, but herein a scene of news report is displayed on a separate screen 44. The news video including character information on snow coverage in every region of Japan is displayed on the screen 40 of an arbitrary display of the display device 21 shown in FIG. 9B in the same manner as FIG. 4, but herein, instead of displaying the scene of news report shown in FIG. 9A, the character information of “TOKAMACHI . . . 279 cm/NAGAOKA . . . 130 cm” is displayed on a separate screen 45 as a telop 43.

With such a configuration, since only a feature image is extracted to display the telop on a separate screen, the user can easily view the news content such as the snow coverage, so that the user can grasp the news content even when he or she is busy and therefore may not carefully view the screen 40a. Further, by displaying the telop on the separate screen, the characters can be read clearly by the user, even in the case where the characters might be too small to be clearly read if being displayed on a slave screen.

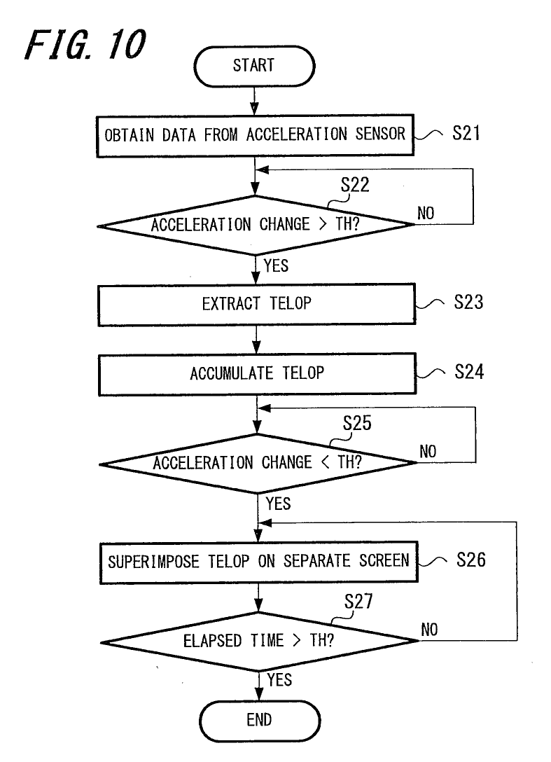

FIG. 10 is a flowchart explaining a reproduction processing as further another information presentation form, in which a telop is superimposed on a separate screen.

In step S21, the sensor data receiving section 33 receives the acceleration data from the acceleration sensor detector 31, and the processing proceeds to step S22.

In step S22, the controller 4 acquires the acceleration data from the sensor data receiving section 33 and determines whether or not the acceleration change of the acceleration data is equal to or greater than a threshold TH. If it is determined that the acceleration change is smaller than the threshold TH, then the determination processing continues.

In step S23, if it is determined in the determination processing of step S22 that the acceleration change is equal to or greater than the threshold TH, then the controller 4 determines that user's busy-level is high, and transmits control data to the telop extracting section 7 to make it extract the telop from the video data of the information (content) to be presented. Thereafter, the processing proceeds to step S24.

In step S24, the telop extracting section 7 accumulates the extracted telop (the content of the character information 42, for example) in the HDD 9, and the processing proceeds to step S25.

In step S25, the controller 4 determines whether or not the acceleration change is smaller than the threshold TH. If it is determined that the acceleration change is equal to or higher than the threshold TH, then the processing returns to step S23 to continue extracting the telop.

In step S26, if it is determined in the determination processing of step S25 that the acceleration change is smaller than the threshold TH, then the controller 4 determines that user's busy-level is low and therefore the user is in the state that allows he or she to view the display, and transmits control data to the telop superimposing section 19 to make it superimpose the telop on the separate screen (see FIG. 9A). At this time, the accumulated telops are collectively displayed in a predetermined place of the separate screen. Thereafter, the processing proceeds to step S27.

In step S27, the controller 4 determines whether or not the elapsed time since the telop has been superimposed on, for example, the separate screen 45 is equal to or longer than a threshold TH. If it is determined that the elapsed time is shorter than the threshold TH, then the processing returns to step S26 to continue displaying the telop on the separate screen (see FIG. 9B, for example). Similar to the example of superimposing a telop on a slave screen, in the case where the user can set the threshold of the elapsed time previously, information can be acquired further efficiently, and operability can be further improved.

On the other hand, if it is determined that the elapsed time is equal to or longer than the threshold TH, then the reproduction processing accompanying processing of superimposing the telop on the separate screen is terminated.

Acquisition of the acceleration data by the acceleration sensor detector 31 is performed at a predetermined timing or periodically. Thus, when a certain time elapses after a series of the aforesaid reproduction processing is terminated, the processing shown in the flowchart of FIG. 10 will be restarted to repeat the reproduction processing accompanying processing of superimposing the telop on the separate screen.

With such a configuration, the presentation form of the information (the content) presented can be properly changed according to user's busy-level (i.e., user's behavior state).

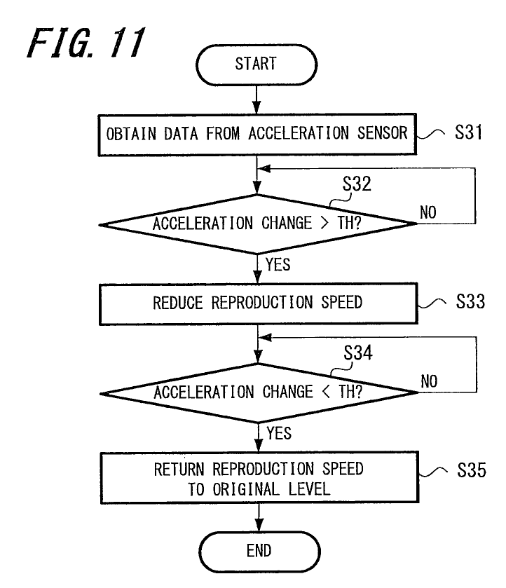

As further another information presentation form, a reproduction processing in which presentation speed adjustment is performed will be described below with reference to the flowchart of FIG. 11.

In step S 31, the sensor data receiving section 33 receives the acceleration data from the acceleration sensor detector 31, and the processing proceeds to step S32.

In step S32, the controller 4 acquires the acceleration data from the sensor data receiving section 33 and determines whether or not the acceleration change of the acceleration data is equal to or greater than the threshold TH. If it is determined that the acceleration change is smaller than a threshold TH, then the determination processing continues. In such a case, the reproduction speed remains at normal level.

In step S33, if it is determined in the determination processing of step S32 that the acceleration change is equal to or greater than the threshold TH, then the controller 4 determines that user's busy-level is high, and transmits control data to the reproduction speed adjusting section 18 to make it reduce the reproduction speed of the content. Thereafter, the processing proceeds to step S34. In the case where the user can set the reproduction speed previously, information can be acquired further efficiently, and operability can be further improved.

In step S34, the controller 4 determines whether or not the acceleration change is smaller than the threshold TH. If it is determined that the acceleration change is equal to or greater than the threshold TH, then the determination processing continues. In such a case, the reproduction speed is at low level.

In step S35, if it is determined in the determination processing of step S34 that the acceleration change is smaller than the threshold TH, then the controller 34 determines that user's busy-level is low, and transmits control data to the reproduction speed adjusting section 18 to make it return the reproduction speed to the original level. When this process is finished, the reproduction processing accompanying reproduction speed adjustment is terminated.

Acquisition of the acceleration data by the acceleration sensor detector 31 is performed at a predetermined timing or periodically. Thus, when a certain time elapses after a series of the aforesaid reproduction processing is terminated, the processing shown in the flowchart of FIG. 11 will be restarted to repeat the reproduction processing accompanying reproduction speed adjustment.

With such a configuration, the presentation form of the information (content) presented can be properly changed according to user's busy-level (i.e., user's behavior state).

Incidentally, although the information is displayed on the display device 21 in the present example, obviously the information may also be displayed on the display 14.

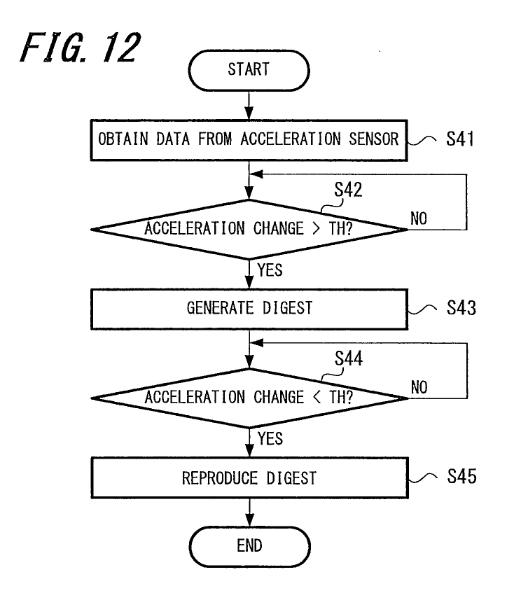

As further another information presentation form, a reproduction processing in which digest reproduction is performed will be described below with reference to the flowchart of FIG. 12.

In step S41, the sensor data receiving section 33 receives the acceleration data from the acceleration sensor detector 31, and the processing proceeds to step S42.

In step S42, the controller 4 acquires the acceleration data from the sensor data receiving section 33 and determines whether or not the acceleration change of the acceleration data is equal to or greater than a threshold TH. If it is determined that the acceleration change is smaller than the threshold TH, then the determination processing continues. In such a case, the content remains in its normal state.

In step S43, if it is determined in the determination processing of step S42 that the acceleration change is equal to or greater than the threshold TH, then the controller 4 determines that user's busy-level is high, and transmits control data to the digest generating section 8 to make it generate a digest of the content. The generated digest version of the content is temporarily accumulated in the HDD 9. Thereafter, the processing proceeds to step S44.

In step S44, the controller 4 determines whether or not the acceleration change is smaller than the threshold TH. If it is determined that the acceleration change is equal to or greater than the threshold TH, then the determination processing continues.

In step S45, if it is determined in the determination processing of step S44 that the acceleration change is smaller than the threshold TH, then the controller 4 determines that user's busy-level is low, and allows the digest version of the content accumulated in the HDD 9 to be outputted through the information processor and the output processor 20 to perform digest reproduction. When this process is finished, the reproduction processing accompanying digest reproduction is terminated.

Acquisition of the acceleration data by the acceleration sensor detector 31 is performed at a predetermined timing or periodically. Thus, when a certain time elapses after a series of aforesaid reproduction processing is terminated, the processing shown in the flowchart of FIG. 12 will be restarted to repeat the reproduction processing accompanying digest reproduction.

With such a configuration, the presentation form of the information (content) presented can be properly changed according to user's busy-level (i.e., user's behavior state).

Incidentally, when reproducing the digest, real-time images (programs) and the digests may also be displayed on a plurality of screens respectively. Also, although the information is displayed on the display device 21 in the present example, obviously the information may be displayed on the display 14. In another possible configuration, for example, a certain screen is assigned to display the digest only, not displaying any real-time image. In further another possible configuration, the user can operate the transmitter 5 to reproduce the generated digests when he or she is not busy.

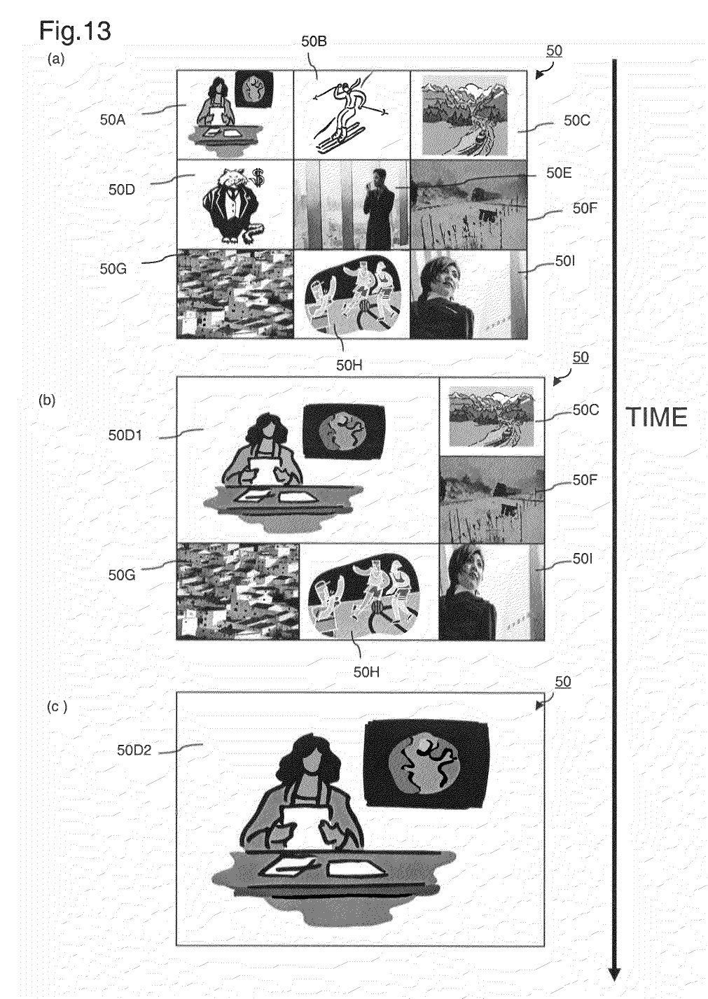

A reproduction processing accompanying enlargement/reduction of the video data in the case where a plurality of displays are provided (i.e., in the case where the display device 21 is used) will be described below with reference to FIGS. 13 to 15.

FIG. 13 shows an example in which the number of programs displayed using the displays of the display device 21 is reduced in the case where the acceleration change of the acceleration data detected by the acceleration sensor detector 31 is large. In the present example, the image is enlarged in the order of (a)→(b)→13(c) of FIG. 13. In (a) of FIG. 13, nine small images 50A to 50I are displayed on a screen 50; in (b) of FIG. 13, one intermediate image 50D1 and five small images 50C, 50F, 50G, 50H, 50I are displayed on the screen 50; and in (c) of FIG. 13, a large image 50D2 is displayed on the screen 50.

With such a configuration, since the image becomes large while the number of the programs becomes small according to user's state, the user can easily view the displayed content so as to reliably grasp the content of the programs even when he or she is busy and therefore may not carefully view the screen 50.

Priority of program (i.e., broadcasting channel) to be displayed in an enlarged manner or priority of the display area (the small image 50A in the present example) designated to display the enlarged image is previously decided. For example, in a possible configuration, a menu screen prompting the user to select a program (broadcasting channel) is displayed to allow the user to previously select a program (broadcasting channel) to be displayed in an enlarged manner or a display area and register the selected item in the HDD 9 or the like. The program (broadcasting channel) to be displayed in an enlarged manner may also by decided based on a past view history or the like.

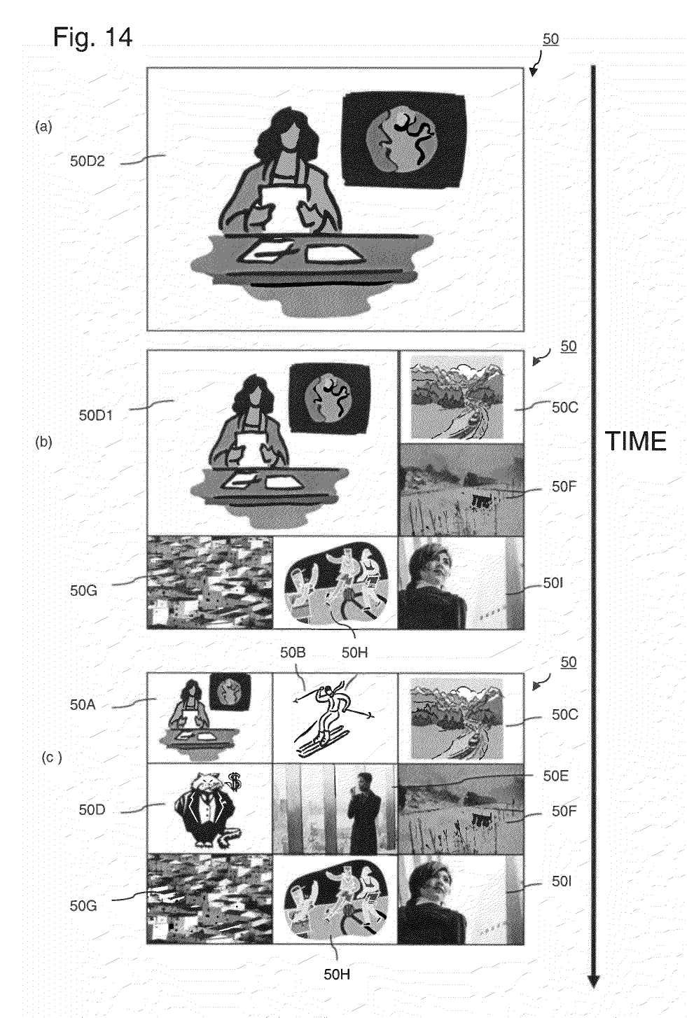

Contrary to the case shown in FIG. 13, FIG. 14 shows an example in which the number of programs displayed using the displays of the display device 21 is increased in the case where the acceleration change of the acceleration data detected by the acceleration sensor detector 31 is small. In the present example, the image is reduced in the order of (a)→(b)→(c) of FIG. 14. In (a) of FIG. 14, one large image 50D2 is displayed on the screen 50; in (b) of FIG. 14, one intermediate image 50D1 and five small images 50C, 50F, 50G, 50H, 50I are displayed on the screen 50; and in (c) of FIG. 14, nine small images 50A to 50I are displayed on the screen 50.

With such a configuration, since the image becomes small while the number of the programs becomes large according to user's state, the user can obtain more information and therefore acquire more information when user's busy-level is low and therefore can carefully view the screen 50.

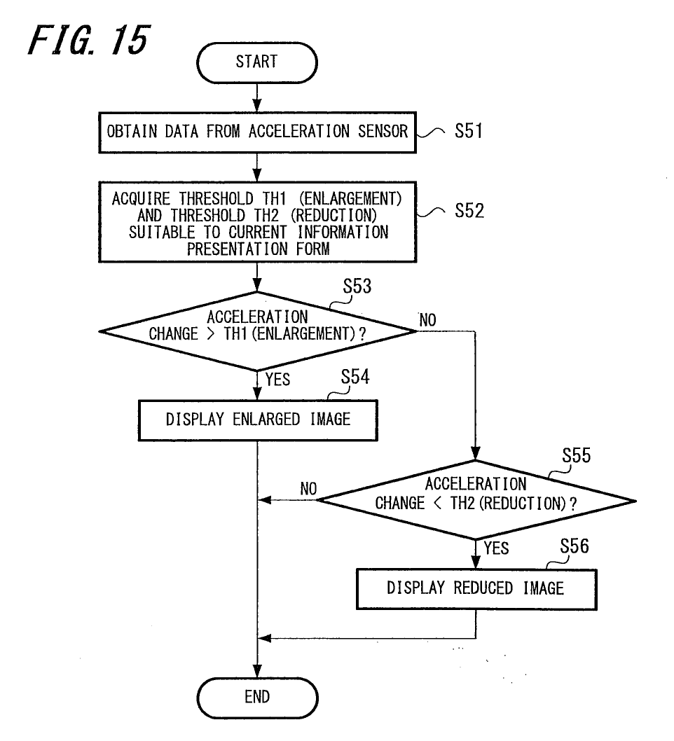

As further another information presentation form, a reproduction processing accompanying enlargement/reduction processing will be described below with reference to the flowchart of FIG. 15. Herein, the current information presentation form is in the state of (b) of FIG. 13 or state of (b) of FIG. 14.

In step S51, the sensor data receiving section 33 receives the acceleration data from the acceleration sensor detector 31, and the processing proceeds to step S52.

In step S52, the controller 4 acquires a threshold TH1 (enlargement) and a threshold TH2 (reduction) of the acceleration change suitable to the current information presentation form from the HDD 9 or a semiconductor memory (not shown). Thereafter, the processing proceeds to step S53.

In step S53, the controller 4 determines whether or not the acceleration change acquired from the sensor data receiving section 33 is equal to or greater than the threshold TH1 (enlargement). If it is determined that the acceleration change is equal to or greater than the threshold TH1, then the processing proceeds to step S54. While if it is determined that the acceleration change is smaller than the threshold TH1, then the processing proceeds to determination processing of step S55.

In step S54, if it is determined in the determination processing of step S53 that the acceleration change is equal to or greater than the threshold TH1, then the controller 4 determines that user's busy-level is high, and transmits control data to the enlargement/reduction processor 16 to make it enlarge the image size of the content when reproduced. The content whose image size has been enlarged is outputted to the display device 21 through the image processor 20a of the output processor 20, and displayed on a plurality of displays in an enlarged manner (from (b) to (c) of FIG. 13). The number of the programs is reduced when displaying the image in an enlarged manner. When this process is finished, the reproduction processing accompanying the enlargement/reduction processing is terminated.

In step S55, the controller 4 determines whether or not the acceleration change is equal to or smaller than the threshold TH2 (reduction). If it is determined that the acceleration change is larger than the threshold TH2, then the reproduction processing accompanying the enlargement/reduction processing is terminated. While if it is determined that the acceleration change is equal to or smaller than the threshold TH2, then the processing proceeds to step S56.

In step S56, if it is determined in the determination processing of step S55 that the acceleration change is equal to or smaller than the threshold TH2, then the controller 4 determines that user's busy-level is low, and transmits control data to the enlargement/reduction processor 16 to make it reduce the size of the content when reproduced so that images are displayed on the plurality of displays respectively. The contents having reduced image size are outputted to the display device 21 through the image processor 20a of the output processor 20, and respectively displayed on the plurality of displays in a reduced manner (from (b) to (c) of FIG. 14). The number of the programs is increased when displaying the image in a reduced manner. When this process is finished, the reproduction processing accompanying the enlargement/reduction processing is terminated.

Acquisition of the acceleration data by the acceleration sensor detector 31 is performed at a predetermined timing or periodically. Thus, when a certain time elapses after a series of the aforesaid reproduction processing accompanying the enlargement/reduction processing is terminated, the processing shown in the flowchart of FIG. 15 will be restarted to determine whether or not the enlargement/reduction processing should be performed. Thus, display form is properly changed in the order of (a)→(b)→(c) of FIG. 13, or in the order of (a)→(b)→(c) of FIG. 14, according to user's busy-level.

With such a configuration, the presentation form of the information (the content) presented can be properly changed according to user's busy-level (i.e., user's behavior state).

Incidentally, although it is assumed in the present example that the current information presentation form is in the state of (b) of FIG. 13 or state of (b) of FIG. 14, it can also be assumed that the current information presentation form is in a minimal state of the reduced display or a maximal state of the reduced display. For example, in the case where the current information presentation form is in the maximal state of the reduced display shown in (a) of FIG. 14, of the threshold TH1 (magnification) and the threshold TH2 (reduction) suitable to such an information presentation form, the threshold TH1 (magnification) can be set to a very value, so that the enlargement processing is not performed anymore. As another example, the controller 4 may acquire the threshold TH2 (reduction) only to skip the determination processing for displaying the image in an enlarged manner (step S53), so that only the determination processing for displaying the image in an reduced manner (step S55) is performed.

Further, although the information is displayed on the display device 21 in the present example, obviously the information may also be displayed on the display 14.

As described above, in a system capable of continuously viewing the image, for example, various processing such as adjusting the image reproduction speed, adjusting sound volume, extracting a telop and displaying the telop in an enlarged manner can be performed according to user's state determined based on the acceleration change detected by the acceleration sensor held by the user, the biological information and the image information. Further, in a system in which a plurality of image presentation devices are installed, the information can be easily obtained according to user's state using methods such as enlarging the image and displaying the enlarged image on a multi-screen.

Incidentally, although the user's busy-level is determined based on the sensor data received by the sensor data receiving section in the aforesaid embodiment, the present invention includes a configuration in which the user can declare his or her busy-level using the transmitter 5. Based on user's busy-level declared by the user and received through the remote control receiving section 6, the controller properly changes the information presentation form.

It should be understood by those skilled in the art that various modifications, combinations, sub-combinations and alterations may occur depending on design requirements and other factors insofar as they are within the scope of the appended claims or the equivalents thereof.

What is claimed is:

1. An information processing device comprising:
a busy-level acquiring section for acquiring information on user's busy-level;
a controller for determining a presentation form of information currently presented according to the user's busy-level acquired by the busy-level acquiring section;
an information processor for performing a predetermined processing to the information under the control of the controller; and
an output processor for outputting the information having been subjected to the processing by the information processor to an output section.

2. The information processing device according to claim 1, wherein the information on the user's busy-level is information indicating a behavior state of the user at present.

3. The information processing device according to claim 2, further comprising:
a sensor data receiving section for receiving sensor data detected by a sensor for detecting the behavior state of the user,
wherein, based on the sensor data of the user received by the sensor data receiving section from the sensor, the controller estimates the user's busy-level at present and determines the presentation form of the information currently presented.

4. The information processing device according to claim 3, wherein the sensor is an acceleration sensor for detecting acceleration of movement of the user, and
wherein, based on the acceleration data of the user received by the sensor data receiving section from the acceleration sensor, the controller estimates the user's busy-level at present and determines the presentation form of the information currently presented.

5. The information processing device according to claim 3, wherein the sensor is a biological information sensor for detecting biological information of the user, and
wherein, based on the biological information data of the user received by the sensor data receiving section from the biological information sensor, the controller estimates the user's busy-level at present and determines the presentation form of the information currently presented.

6. The information processing device according to claim 2, further comprising:
an operation signal receiving section for receiving an operation signal from an operation unit,
wherein the operation signal receiving section receives the operation signal based on a declaration issued by the user using the operation unit and supplies the received operation signal to the controller, the declaration indicating the information on the user's busy-level.

7. The information processing device according to claim 3 or 6,
wherein the information processor includes a sound volume adjusting section for adjusting sound volume of audio data included in the information under the control of the controller, and
wherein the output processor supplies the audio data having been subjected to the sound volume adjusting to a speaker.

8. The information processing device according to claim 3 or 6, further comprising:
a telop extracting section for extracting a telop from video data included in the information under the control of the controller,
wherein the information processor supplies information including the telop to the output processor.

9. The information processing device according to claim 8, wherein the information processor includes a telop superimposing section for performing a superimposing processing so that the extracted telop is displayed as a slave screen of the image based on the video data.

10. The information processing device according to claim 8, wherein the information processor includes a telop superimposing section for performing a superimposing processing so that the extracted telop is displayed as a separate screen relative to the image based on the video data.

11. The information processing device according to claim 8,
wherein the information processor converts the content of the telop extracted by the telop extracting section into audio data, and
wherein the output processor supplies the audio data to a speaker.

12. The information processing device according to claim 3 or 6,
wherein the information processor includes a reproduction speed adjusting section for adjusting reproduction speed of the information, and
wherein the reproduction speed adjusting section adjusts the reproduction speed of the information under the control of the controller and supplies the result to the output processor.

13. The information processing device according to claim 3 or 6, wherein the information processor includes a digest generating section for generating a digest of video data included in the information under the control of the controller and supplying the generated digest to the output processor.

14. The information processing device according to claim 3 or 6, wherein the information processor includes an enlargement/reduction processor for, under the control of the controller, performing enlargement/reduction processing to enlarge/reduce screen size of video data included in the information and change the number of the contents simultaneously displayed on a plurality of output sections.

15. An information processing method of an information processing device for presenting information to an output section based on information relating to a user, the method comprising steps of:
acquiring information on user's busy-level;
determining a presentation form of information currently presented according to the acquired user's busy-level;
performing a predetermined processing to the information currently presented based on the determined presentation form; and
outputting the information having been subjected to the predetermined processing to the output section.
